(19) United States
(12) Patent Application Publication
(10) Pub. No.: US 2023/0411533 A1
(43) Pub. Date: Dec. 21, 2023

(54) MULTI-STATE FIELD EFFECT TRANSISTOR DEVICE

(71) Applicant: INTERNATIONAL BUSINESS MACHINES CORPORATION, ARMONK, NY (US)

(72) Inventors: Karthik Yogendra, Hillsboro, OR (US); Maruf Amin Bhuiyan, Albany, NY (US); Kangguo Cheng, Schenectady, NY (US)

(21) Appl. No.: 17/806,952

(22) Filed: Jun. 15, 2022

(51) Int. Cl. H01L 29/792; H01L 29/78

(52) U.S. Cl. CPC H01L 29/792; H01L 29/7846; H01L 29/785

(57) ABSTRACT

Embodiments of present invention provide a transistor structure. The transistor structure includes a composite channel of multiple channel layers of different materials, wherein the multiple channel layers are separated from each other by an isolation layer and a material of the isolation layer has a bandgap that is wider than bandgaps of the different materials of the multiple channel layers; a charge trapping layer surrounding the composite channel; a gate metal surrounding the charge trapping layer; and source/drain regions at a first and a second end of the composite channel. A method of forming the same is also provided.

### BACKGROUND

The present application relates to manufacturing of semiconductor integrated circuits. More particularly, it relates to a transistor with multiple states and method of manufacturing the same.

As semiconductor industry moves towards smaller node, for example 7-nm node and beyond, field-effect-transistors (FETs) are aggressively scaled in order to fit into the reduced footprint or real estate, as defined by the node, with increased device density. Among various types of FETs, non-planar FETs such as fin-type FETs, vertical FETs, nanosheet FETs and/or nanowire FETs are just some examples that have shown some potentials to at least partially meet this continued device scaling needs. On the other hand, logic transistors with multiple output values may further mitigate this ever-increasing demand for real estate of footprint as well. When being compared with the conventional binary transistor, a logic transistor with multiple output values may provide a result that would otherwise require the combination of multiple binary transistors to achieve.

### SUMMARY

With the ever-increasing number of applications such as for example in the artificial intelligence (AI) field, the demand for reliable logic transistors with multiple output values, i.e., multi-value logic transistors, with high endurance is higher than ever before. A multi-value logic transistor may be achieved through, for example, a field-effect-transistor with multiple states.

Embodiments of present invention provide a multi-state field effect transistor (MSFET). The MSFET includes a composite channel of multiple channel layers of different materials, wherein the multiple channel layers are separated from each other by an isolation layer and a material of the isolation layer has a bandgap that is wider than bandgaps of the different materials of the multiple channel layers; a charge trapping layer surrounding the composite channel; a gate metal surrounding the charge trapping layer; and source/drain regions at a first and a second end of the composite channel.

In one embodiment, the multiple channel layers are made of materials of aluminum-gallium-nitride of different aluminum and gallium fractions as being expressed as AlₓGa₁₋ₓN with x varying from 0 to about 0.6. For example, in one aspect, x of AlₓGa₁₋ₓN of the different materials of the multiple channel layers varies linearly from a bottom-most layer to a top-most layer.

In another embodiment, the isolation layer includes the material of aluminum-nitride (AlN). In yet another embodiment, the charge trapping layer is a layer of oxide-nitride-oxide (ONO), silicon-nitride (SiN), or ferroelectric oxide.

In one embodiment, the multiple channel layers have different bandgaps that range from about 3.0 eV to about 4.6 eV and the isolation layer has a bandgap of about 6.0 eV. In one aspect, the multiple channel layers include eight channel layers, and the eight channel layers have a bandgap difference of approximately 0.2 eV, such as 0.22 eV, between any two adjacent channel layers.

Embodiments of present invention provide a method of forming a transistor structure. The method includes epitaxially growing multiple channel layers of AlₓGa₁₋ₓN material with each of the multiple channel layers being separated by an isolation layer; patterning the multiple channel layers into a composite channel; forming a charge trapping layer surrounding the composite channel; forming a gate metal surrounding the charge trapping layer; and forming source/drain regions at a first and a second end of the composite channel.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B are demonstrative illustrations of cross-sectional views of a multi-state field effect transistor device according to one embodiment of a method of present invention;

FIG. 2 is a demonstrative illustration of cross-sectional view of a multi-state field effect transistor device in a step of manufacturing thereof according to one embodiment of present invention;

FIG. 3 is a demonstrative illustration of cross-sectional view of a multi-state field effect transistor device in a step of manufacturing thereof, following the step illustrated in FIG. 2, according to one embodiment of present invention;

FIG. 4 is a demonstrative illustration of cross-sectional view of a multi-state field effect transistor device in a step of manufacturing thereof, following the step illustrated in FIG. 3, according to one embodiment of present invention;

FIG. 5 is a demonstrative illustration of cross-sectional view of a multi-state field effect transistor device in a step of manufacturing thereof, following the step illustrated in FIG. 4, according to one embodiment of present invention;

FIG. 6 is a demonstrative illustration of cross-sectional view of a multi-state field effect transistor device in a step of manufacturing thereof, following the step illustrated in FIG. 5, according to one embodiment of present invention;

FIG. 7 is a demonstrative illustration of cross-sectional view of a multi-state field effect transistor device in a step of manufacturing thereof, following the step illustrated in FIG. 6, according to one embodiment of present invention;

FIG. 8 is a demonstrative illustration of cross-sectional view of a multi-state field effect transistor device in a step of manufacturing thereof, following the step illustrated in FIG. 7, according to one embodiment of present invention; and

FIG. 9 is a demonstrative illustration of a flow-chart of a method of manufacturing a multi-state field effect transistor device according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

To provide spatial context to different structural orientations of the semiconductor structures shown in the drawings, XYZ Cartesian coordinates may be provided in some of the drawings. The terms “vertical” or “vertical direction” or “vertical height” as used herein denote a Z-direction of the Cartesian coordinates shown in the drawings, and the terms “horizontal” or “horizontal direction” or “lateral direction” as used herein denote an X-direction and/or a Y-direction of the Cartesian coordinates shown in the drawings.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

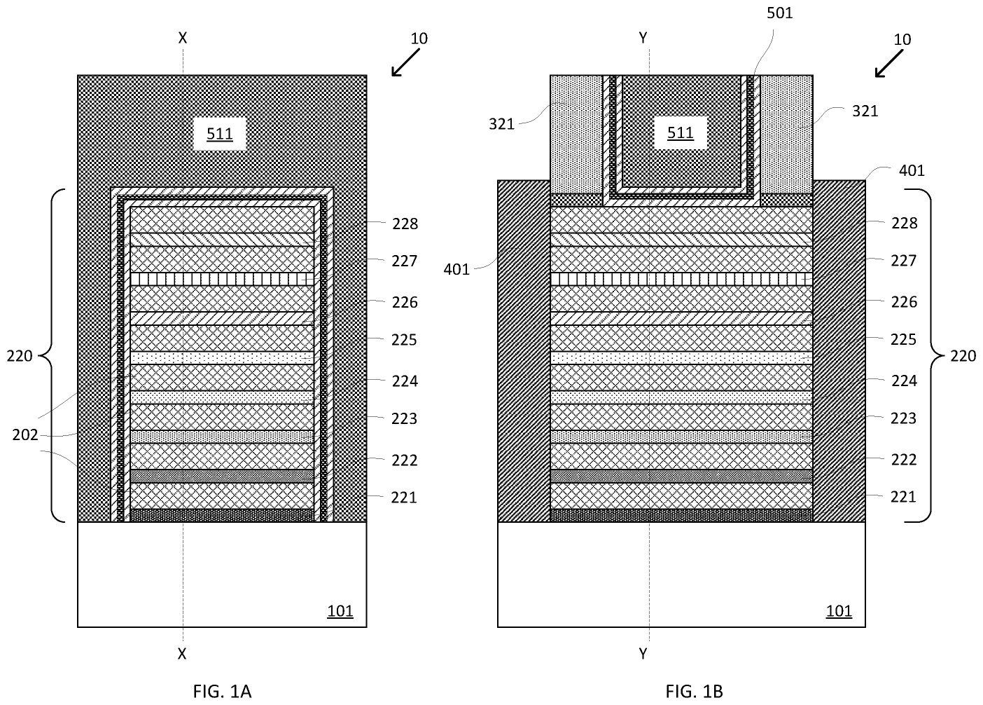

FIGS. 1A and 1B are demonstrative illustrations of cross-sectional views of a multi-state field effect transistor device according to one embodiment of present invention. More specifically, FIG. 1A is a cross-sectional view of a multi-state field-effect-transistor (MSFET) 10 taken along a dashed line Y-Y (see FIG. 1B) in a direction parallel to the gate of the MSFET 10, and FIG. 1B is a cross-sectional view of the MSFET 10 taken along a dashed line X-X (see FIG. 1A) in a direction perpendicular to the gate of the MSFET 10, that is, in a direction from a first source/drain (S/D) region to as a second S/D region of the MSFET 10.

More particularly, in one embodiment, MSFET 10 includes a substrate 101 upon which a composite channel 220 is formed. The composite channel 220 may include multiple channel layers such as, for example, eight (8) channel layers of different materials. Here, a person skilled in the art will appreciate that the number of channel layers are not limited to eight. For example, different number of channel layers such as 4, 12, or even 16 are possible and these different number of channel layers are all contemplated herein as being within the spirit of embodiments of the present invention. Hereinafter, the composite channel 220 is assumed to have eight channel layers for the sake of description.

The eight channel layers may include, for example, channel layers 221, 222, 223, 224, 225, 226, 227, and 228. The eight channel layers may be made of materials such as, for example, aluminum-gallium-nitride and may each have a material composition of different aluminum (Al) and gallium (Ga) fractions. For example, materials of the eight channel layers may be expressed as AlₓGa₁₋ₓN with x varying from, for example, about 0 to about 0.6.

According to one embodiment of present invention, x of AlₓGa₁₋ₓN may vary linearly or substantially linearly from a bottom-most layer to a top-most layer of the eight channel layers of the composite channel 220. For example, x may vary from about 0.6 to about 0 or from about 0 to about 0.6. Further for example, in one embodiment, from the bottom-most layer 221 to the top-most layer 228 of the eight channel layers, x may be about 0.600, 0.515, 0.430, 0.345, 0.260, 0.175, 0.090, and 0 respectively.

According to another embodiment of present invention, materials of the multiple channel layers may be AlₓGa₁₋ₓN or any other suitable materials. More specifically, materials of the multiple channel layers may have different bandgaps, and the bandgaps may vary from, for example, about 3.0 eV to about 4.6 eV. For example, in the above example of eight channel layers, the bandgaps between any two neighboring channel layers may have a difference of about 0.2 eV such as, for example, 0.22 eV. For example, from the bottom-most layer 221 to the top-most layer 228, the eight channel layers may respectively have bandgaps of about 4.60 eV, 4.38 eV, 4.16 eV, 3.98 eV, 3.72 eV, 3.50 eV, 3.28 eV, and 3.00 eV.

As being demonstratively illustrated in FIGS. 1A and 1B, the multiple channel layers may be separated from each other by an isolation layer 202. In other words, between any two neighboring channel layers there is an isolation layer 202. The isolation layer 202 may have a bandgap that is higher than that of any of the multiple channel layers. On the other hand, the isolation layer 202 may have a lattice constant that is similar to those of the multiple channel layers. In one embodiment, the isolation layer 202 may be made of aluminum-nitride (AlN) to have a bandgap of about 6.0 eV, although other suitable materials that have a bandgap wider than those of the multiple channel layers, but similar lattice constant may be used as well. The isolation layers 202 that separate the channel layers may have a same or different thickness.

The MSFET 10 may further have a gate that includes a charge trapping layer 501 surrounding the composite channel 220 and a gate metal 511 on top of the charge trapping layer 501. The charge trapping layer 501 may be a layer of oxide-nitride-oxide (ONO), silicon-nitride, or ferroelectric oxide. The gate of MSFET 10 may be formed through a replacement-metal-gate (RMG) process, as being described below in more details, with sidewall spacers 321. The MSFET 10 may further include a first and a second source/drain (S/D) regions 401 at a first and a second end of the multiple channel layers.

According to embodiments of present invention, the multiple channel layers of the MSFET 10 may have different threshold voltages and the threshold voltages may be a function of its material composition, i.e., bandgaps of the material composition. The threshold voltage increases as the material composition changes from pure GaN, with a bandgap around 3.0 eV, to AlₓGa₁₋ₓN, with a bandgap around 4.6 eV when x equals 0.6. Depending on how many channel layers are programed, i.e., programed at above or below their respective threshold voltages, the MSFET 10 may provide an output current corresponding to the number of channel layers being programed and/or activated. Therefore, the MSFET 10 may serve as a multi-value logic transistor.

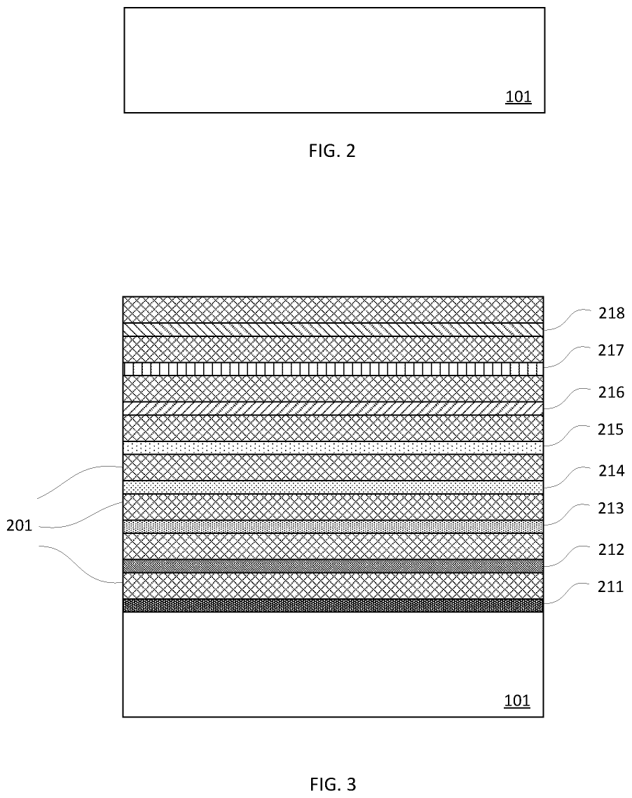

FIGS. 2-8 are demonstrative illustrations of cross-sectional views of a multi-state field effect transistor device during a process of manufacturing thereof according to embodiments of present invention. More particularly, FIGS. 2-8 illustrates cross-sectional views of the multi-state field effect transistor, similar to FIG. 1B, made along a dashed line X-X (see FIG. 1A) in a direction perpendicular to the gate of the MSFET 10. In other words, the cross-sectional view is in a direction from a first source/drain (S/D) region to a second S/D region of the MSFET 10.

More specifically, FIG. 2 is a demonstrative illustration of cross-sectional view of a multi-state field effect transistor device in a step of manufacturing thereof according to one embodiment of present invention. More specifically, embodiments of present invention provide starting with a substrate 101 such as receiving a substrate 101. The substrate 101 may be a bulk silicon (Si) substrate, germanium (Ge) substrate, silicon-germanium (SiGe) composite substrate, a silicon-on-insulator (SOI) substrate, or any other suitable substrate.

FIG. 3 is a demonstrative illustration of cross-sectional view of a multi-state field effect transistor device in a step of manufacturing thereof, following the step illustrated in FIG. 2, according to one embodiment of present invention. More specifically, embodiments of present invention provide epitaxially growing a plurality of channel layers such as channel layers 211, 212, 213, 214, 215, 216, 217, and 218 on top of the substrate 101. The channel layers 211-218 may have different bandgaps varying from about 3.00 eV to about 4.60 eV and may have a bandgap difference between any two adjacent channel layers of about 0.20 eV such as, for example, about 0.22 eV. In one embodiment, the channel layers 211-218 may have bandgaps, from the bottom-most channel layer 211 to the top-most channel layer 218 respectively, of 4.60 eV, 4.38 eV, 4.16 eV, 3.98 eV, 3.72 eV, 3.50 eV, 3.28 eV, and 3.00 eV.

In one embodiment, the channel layers 211-218 may be epitaxially grown aluminum-gallium-nitride AlₓGa₁₋ₓN with x varying from, for example, about 0 to about 0.6. In other words, the channel layers 211-218 may have a material composition of AlₓGa₁₋ₓN with different aluminum and gallium fractions. In some embodiments, x of the AlₓGa₁₋ₓN material composition may vary linearly, from about 0 to about 0.6 or from about 0.6 to about 0, from the bottom-most channel layer 211 to the top-most channel layer 218. For example, x of AlₓGa₁₋ₓN, from the channel layer 211 to the channel layer 218, may be around 0.600, 0.515, 0.430, 0.345, 0.260, 0.175, 0.090, and 0 respectively.

Between any two neighboring channel layers, embodiments of present invention may also provide epitaxially growing an isolation layer 201 that separates the channel layers 211-218. The isolation layer 201 may have a higher bandgap than, but similar lattice constant to, those of the channel layers 211-218 to enable alternating epitaxial growth of the channel layers 211-218 and the isolation layer 201. For example, the isolation layer 201 may include or be made of aluminum-nitride (AlN) to have a bandgap of around 6.00 eV. On the other hand, the isolation layer 201 of AlN material may have sufficiently similar lattice constant to the channel layers 211-218 of aluminum-gallium-nitride AlₓGa₁₋ₓN where x varies from about 0 to about 0.6. The isolation layers 201 may generally have different thickness from those of the channel layers 211-218 and may, among themselves, preferably have similar thicknesses. Embodiments of present invention may also include isolation layers 201 that have different thicknesses.

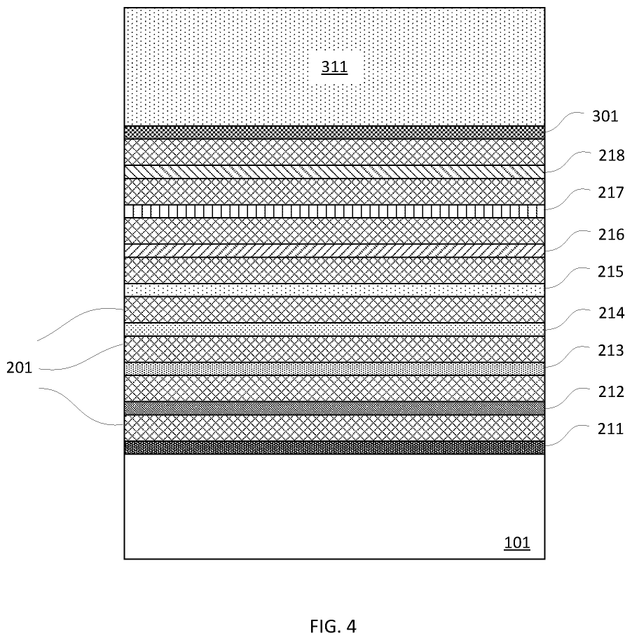

FIG. 4 is a demonstrative illustration of cross-sectional view of a multi-state field effect transistor device in a step of manufacturing thereof, following the step illustrated in FIG. 3, according to one embodiment of present invention. More specifically, embodiments of present invention provide forming a sacrificial oxide layer 301 covering the isolation layer 201 at the top of the stack of channel layers 211-218 and patterning the stack of channel layers 211-218 and the isolation layers 201 into a fin-shape or a strip shape (parallel to the paper). Embodiments of present invention further provide forming a dummy gate 311 such as a polysilicon dummy gate on top of the sacrificial oxide layer 301 as a part of a replacement-metal-gate (RMG) process.

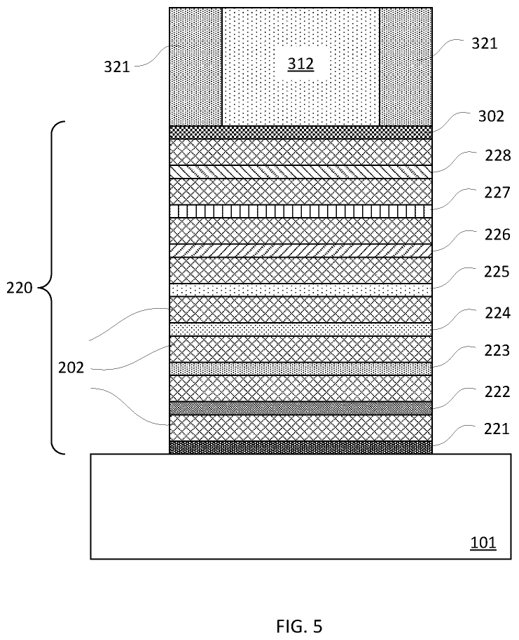

FIG. 5 is a demonstrative illustration of cross-sectional view of a multi-state field effect transistor device in a step of manufacturing thereof, following the step illustrated in FIG. 4, according to one embodiment of present invention. More specifically, embodiments of present invention provide patterning the dummy gate 311 into a dummy gate structure 312 and subsequently forming sidewall spacers 321 next to the dummy gate structure 312. Using the dummy gate structure 312 and sidewall spacers 321 as mask, embodiments of present invention further provide etching the stack of channel layers 211, 212, 213, 214, 215, 216, 217, 218 into a stack of channel layers 221, 222, 223, 224, 225, 226, 227, 228 and the isolation layers 201 into isolation layers 202 thereby forming a composite channel 220. In other words, the composite channel 220 may include the stack of channel layers 221-228 and isolation layers 202 in between the stack of channel layers 221-228. The process also etches sacrificial oxide layer 301 into a sacrificial oxide layer 302.

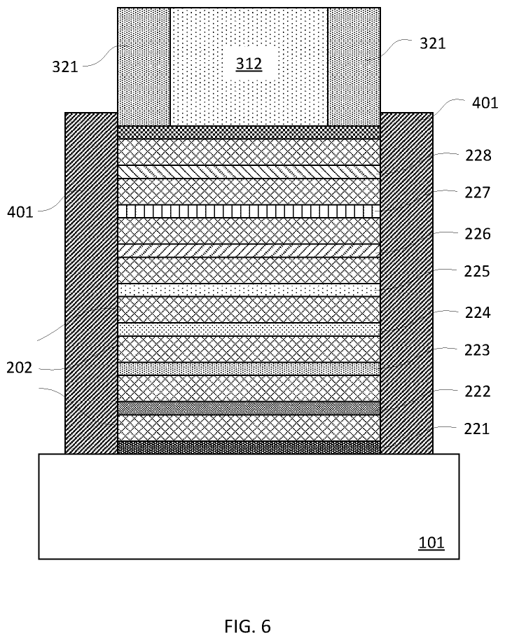

FIG. 6 is a demonstrative illustration of cross-sectional view of a multi-state field effect transistor device in a step of manufacturing thereof, following the step illustrated in FIG. 5, according to one embodiment of present invention. More specifically, embodiments of present invention provide forming a first and a second source/drain (S/D) regions 401 at a first and a second end of the stack of channel layers 221-228 and the isolation layers 202. The S/D regions 401 may be epitaxially grown semiconductor materials such as, for example, silicon-germanium (SiGe) materials. Other suitable material such as those that may be epitaxially grown on top of substrate 101 and/or at the two ends of the channel layers 221-228 of AlₓGa₁₋ₓN materials may be used as well.

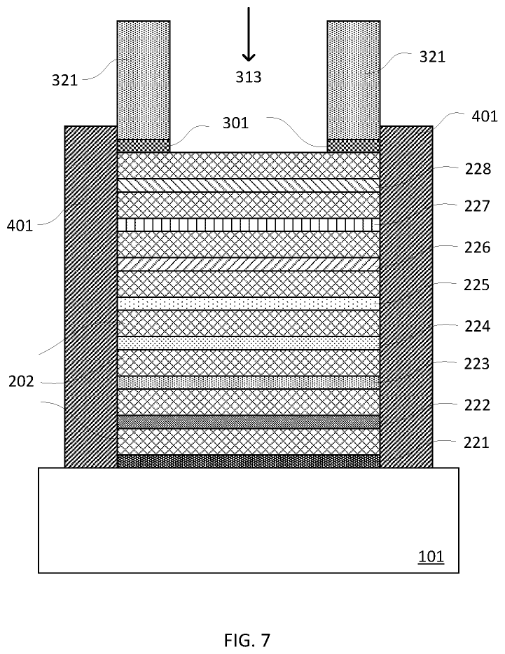

FIG. 7 is a demonstrative illustration of cross-sectional view of a multi-state field effect transistor device in a step of manufacturing thereof, following the step illustrated in FIG. 6, according to one embodiment of present invention. More specifically, embodiments of present invention provide selectively removing dummy gate structure 312, and a portion of the sacrificial oxide layer 301 underneath the dummy gate structure 312, to create an opening 313 between the sidewall spacers 321 in a step of an RMG process that forms gate metal for the MSFET 10 as being described below in more details.

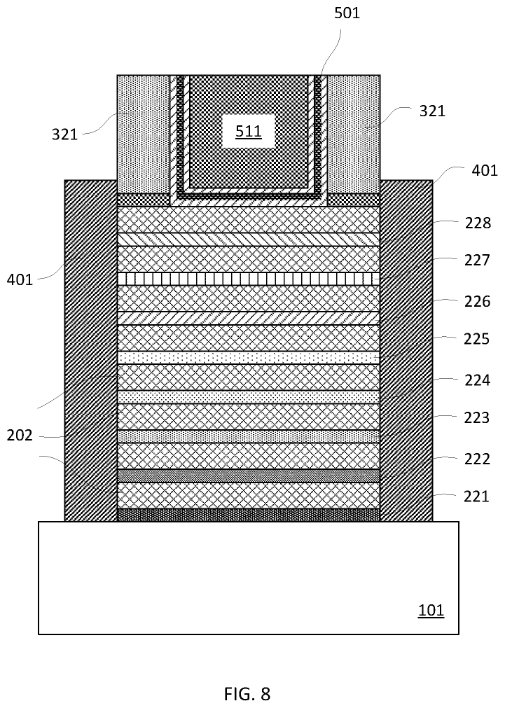

FIG. 8 is a demonstrative illustration of cross-sectional view of a multi-state field effect transistor device in a step of manufacturing thereof, following the step illustrated in FIG. 7, according to one embodiment of present invention. More specifically, embodiments of present invention provide forming a gate of the MSFET 10 including forming a charge trapping layer 501 and a gate metal 511 on top of and surrounding the charge trapping layer 501. For example, the charge trapping layer 501 may be formed in the opening 313 between the sidewall spacers 321 and directly on top of and surrounding the stack of channel layers 221-228 and isolation layers 202 (FIG. 1A). The charge trapping layer 501 may be an oxide-nitride-oxide (ONO) layer, a silicon-nitride (SiN) layer, or a ferroelectric oxide layer. The gate metal 511 may be conductive materials including, for example, tungsten (W), copper (Cu), and cobalt (Co).

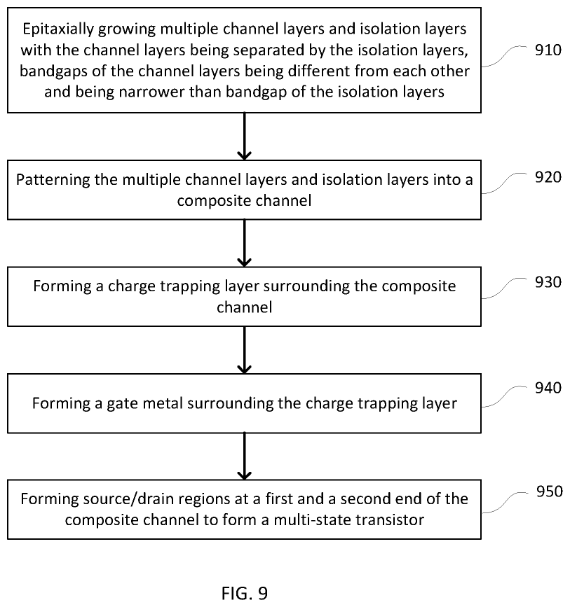

FIG. 9 is a demonstrative illustration of a flow-chart of a method of manufacturing a multi-state field effect transistor device according to embodiments of present invention. More specifically, embodiments of present invention includes (910) epitaxially growing and/or forming multiple channel layers and isolation layers with the channel layers being separated by the isolation layers, wherein bandgaps of the multiple channel layers being different from each other and being smaller or narrower than the bandgap of the isolation layers; (920) patterning the multiple channel layers and isolation layers into a composite channel; (930) forming a charge trapping layer surrounding the composite channel; (940) forming a gate metal surrounding the charge trapping layer; and (950) forming source/drain regions at a first and a second end of the composite channel to form a multi-state field effect transistor.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A transistor structure comprising:
a composite channel of multiple channel layers of different materials, wherein the multiple channel layers are separated from each other by an isolation layer and a material of the isolation layer has a bandgap that is wider than bandgaps of the different materials of the multiple channel layers;
a charge trapping layer surrounding the composite channel;
a gate metal surrounding the charge trapping layer; and
source/drain regions at a first and a second end of the composite channel.

2. The transistor structure of claim 1, wherein the different materials of the multiple channel layers comprise aluminum-gallium-nitride of different aluminum and gallium fractions that are expressed as AlₓGa₁₋ₓN with x varying from 0 to about 0.6.

3. The transistor structure of claim 2, wherein x of AlₓGa₁₋ₓN of the different materials of the multiple channel layers varies linearly from a bottom-most layer to a top-most layer of the multiple channel layers.

4. The transistor structure of claim 1, wherein the material of the isolation layer comprises aluminum-nitride (AlN).

5. The transistor structure of claim 1, wherein the charge trapping layer comprises a layer of oxide-nitride-oxide (ONO), silicon-nitride (SiN), or ferroelectric oxide.

6. The transistor structure of claim 1, wherein the multiple channel layers have different bandgaps ranging from about 3.0 eV to about 4.6 eV and the isolation layer has a bandgap of about 6.0 eV.

7. The transistor structure of claim 1, wherein the multiple channel layers comprise eight channel layers.

8. The transistor structure of claim 1, wherein two adjacent channel layers of the multiple channel layers have a bandgap difference of approximately 0.2 eV.

9. A transistor structure comprising:
a composite channel of eight channel layers of different materials, wherein two adjacent channel layers of the eight channel layers are separated by an isolation layer;
a charge trapping layer surrounding the composite channel;
a gate metal surrounding the charge trapping layer; and
a first and a second source/drain region at a first and a second end of the composite channel respectively.

10. The transistor structure of claim 9, wherein the isolation layer has a bandgap that is wider than a bandgap of each of the eight channel layers.

11. The transistor structure of claim 9, wherein the eight channel layers comprise the different materials of aluminum-gallium-nitride that is expressed as AlₓGa₁₋ₓN, wherein x varies from 0 to 0.6 and is different for each of the eight channel layers.

12. The transistor structure of claim 11, wherein from a bottom-most layer to a top-most layer of the eight channel layers, x of AlₓGa₁₋ₓN of the different materials is about 0.600, 0.430, 0.345, 0.260, 0.175, 0.090, and 0 respectively.

13. The transistor structure of claim 9, wherein the isolation layer comprises aluminum-nitride (AlN).

14. The transistor structure of claim 9, wherein the charge trapping layer comprises oxide-nitride-oxide (ONO), silicon-nitride (SiN), or ferroelectric oxide.

15. The transistor structure of claim 9, wherein from a bottom-most layer to a top-most layer, the eight channel layers respectively have a bandgap of about 4.60 eV, 4.38 eV, 4.16 eV, 3.98 eV, 3.72 eV, 3.50 eV, 3.28 eV, and 3.00 eV, and wherein the isolation layer has a bandgap of about 6.00 eV.

16. A method of forming a transistor structure comprising:
epitaxially growing multiple channel layers of AlₓGa₁₋ₓN material with the multiple channel layers being separated from each other by an isolation layer;
patterning the multiple channel layers into a composite channel;
forming a charge trapping layer surrounding the composite channel;
forming a gate metal surrounding the charge trapping layer; and
forming source/drain regions at a first and a second end of the composite channel.

17. The method of claim 16, wherein the multiple channel layers of AlₓGa₁₋ₓN material have different fractions of aluminum and gallium with x varying from 0 to about 0.6.

18. The method of claim 16, wherein the isolation layer comprises aluminum-nitride (AlN) with a bandgap that is wider than the multiple channel layers of the AlₓGa₁₋ₓN material.

19. The method of claim 16, wherein forming the charge trapping layer comprises forming a layer of oxide-nitride-oxide (ONO), silicon-nitride (SiN), or ferroelectric oxide, the charge trapping layer surrounding the composite channel.

20. The method of claim 16, wherein two adjacent channel layers of the multiple channel layers change have a bandgap difference of about 0.22 eV.
